(19) United States
(12) Patent Application Publication
(10) Pub. No.: US 2013/0100136 A1
(43) Pub. Date: Apr. 25, 2013

(54) SPARKLINE PRESENTATIONS OF PROCESS CONTROL SYSTEM ALARMS

(71) Applicants: Kim Ordean Van Camp, Georgetown, TX (US); Glenn Mclaughlin, Austin, TX (US)

(72) Inventors: Kim Ordean Van Camp, Georgetown, TX (US); Glenn Mclaughlin, Austin, TX (US)

(21) Appl. No.: 13/279,589

(22) Filed: Oct. 24, 2011

(51) Int. Cl. G06T 11/20

(52) U.S. Cl. 345/440

(57) ABSTRACT

Sparkline presentations of process control system alarms are described. An operator interface apparatus for a process control system includes an operator display module to present an operator application on a display. The operator interface also includes an alarm presentation interface to be presented on the display via the operator application. The alarm presentation interface includes a sparkline associated with an alarm to graphically indicate a trend of a process variable relative to an alarm limit associated with the alarm.

### FIELD OF THE DISCLOSURE

This disclosure relates generally to process control systems and, more particularly, to sparkline presentations of process control system alarms.

### BACKGROUND

Process control systems, like those used in chemical, petroleum or other processes, typically include one or more process controllers communicatively coupled to one or more field devices via analog, digital or combined analog/digital buses. The field devices, which may be, for example, valves, valve positioners, switches and transmitters (e.g., temperature, pressure and flow rate sensors), perform process control functions within the process such as opening or closing valves and measuring process control parameters. The process controllers receive signals indicative of process measurements made by the field devices and then process this information to generate control signals to implement control routines, to make other process control decisions, and to initiate process control system alarms. Frequently, process control information may also be recorded for long-term historization for subsequent analysis and/or training.

Information from the field devices and/or the controller is usually made available over a data highway or communication network to one or more other hardware devices such as operator workstations, personal computers, data historians, report generators, centralized databases, etc. Such devices are typically located in control rooms and/or other locations remotely situated relative to the harsher plant environment. These hardware devices, for example, run applications that enable an operator to perform any of a variety of functions with respect to the process of a process control system, such as viewing the current state of the process, changing an operating state, changing settings of a process control routine, modifying the operation of the process controllers and/or the field devices, viewing alarms generated by field devices and/or process controllers, simulating the operation of the process for the purpose of training personnel and/or evaluating the process, etc.

These hardware devices typically include one or more operator interface displays to display pertinent information regarding the operating state(s) of the control system(s) and/or the devices within the control system. Example displays take the form of alarm displays that receive and/or display alarms generated by controllers or devices within the process control system, control displays that indicate the operating state(s) of the controller(s) and other device(s) within the process control system, etc.

In a process control system it is common for thousands of alarms to be defined within the process control system to notify operators of the process control system of potential problems. Alarms are defined, for example, to protect people and/or equipment, to avoid environmental incidents, and/or to ensure product quality during production. Each alarm is typically defined by one or more settings (e.g., an alarm limit) that define when a problem has occurred or may be imminent and/or trigger the alarm, and a priority (e.g., critical or warning) to define the importance of the alarm relative to other alarms.

Typically, alarms are presented (e.g., displayed) to operators in list or tabular format. In such formats, each alarm is presented as a single line in the list with specific data that may be relevant to inform an operator of the state of the control system. Data provided in an alarm list may include, for example, a description of the alarm, the time the alarm was triggered, the source of the alarm, the importance or priority of the alarm, the state of the alarm (e.g., acknowledged or not, active or not), the type of process variable that triggered the alarm, the value of the process variable, etc. As information is received from process controllers and/or field devices, the alarm list data may be updated in real time to allow the operators access to current information regarding all active alarms.

### SUMMARY

Methods and apparatus to present a sparkline presentation of process control system alarms are disclosed. In one example, an operator interface apparatus for a process control system includes an operator display module to present an operator application on a display. The operator interface also includes an alarm presentation interface to be presented on the display via the operator application. The alarm presentation interface includes a sparkline associated with an alarm to graphically indicate a trend of a process variable relative to an alarm limit associated with the alarm.

In another example, a method involves receiving process variable data from a process controller associated with a process variable; receiving alarm data of an alarm associated with the process variable; generating a sparkline based on the process variable data and the alarm data to graphically indicate a trend of the process variable relative to an alarm limit of the alarm; and displaying the sparkline via an operator interface.

### BRIEF DESCRIPTION OF THE DRAWINGS

FIG. 1 is a schematic illustration of an example process control system.

FIG. 2 illustrates an example manner of implementing the example operator station of FIGS. 1 and/or 2.

FIG. 3 illustrates an example alarm presentation interface that may be used to implement an operator display and/or application and/or, more generally, the example operator station of FIG. 1.

FIG. 4 illustrates another example alarm presentation interface.

FIG. 5 is a flowchart representative of an example process for implementing the example operator station of FIGS. 1 and/or 2

FIG. 6 is a schematic diagram of an example processor platform that may be used and/or programmed to carry out the example process of FIG. 5 and/or, more generally, to implement the example operator station of FIGS. 1 and/or 2.

### DETAILED DESCRIPTION

Alarm displays are one of the primary means by which process control system operators remain aware of potential problems in a process control system. A typical alarm display includes a tabulated list of all active alarms. The information presented in an alarm display for each active alarm may include the time of alarm activation, the alarm type (e.g., high, low, etc.), the threshold setting or alarm limit (e.g., 400 gal.) and the process variable measurement (e.g., 408 gal.).

Additionally, alarm displays are typically updated in real time to provide operators with the most current information of the state of a process control system. However, while operators have the most current data regarding process control system alarms, the variation of process variables associated with an active alarm over the time period since the corresponding alarms became active (i.e., the ongoing trends and/or behavior of the process variables) is not readily available for analysis. Without this information, operators may incorrectly interpret the significance and/or meaning of an alarm, which may result in ineffective corrective action. For example, operators may become accustomed to certain commonly occurring alarms based on past experience. From the past experience, operators may make incorrect assumptions about a root cause (i.e., the initial circumstance and/or state of a process control system that causes the alarms) because, although the same commonly occurring alarms are triggered, the process dynamics are different. For example, operators may be accustomed to a process variable that typically has a slow return to a normal (i.e., non-alarm) state due to normal process dynamics and/or because the alarm is improperly configured with too much hysteresis and/or off-delay. As a result, operators may incorrectly ignore such an alarm for a significant time period when swift action is needed because the actual state of the process control system is different than assumed by the operators. In other words, operators may become accustomed to responding to one or more alarms in a certain manner that has been effective in the past (e.g., waiting for a period of time before responding). However, if the actual state of the process control system is different than assumed, but the same alarms are nevertheless signaled, operators may not realize the different state of the control system and, therefore, may respond in their usual manner to little or no effect. Just as failing to appreciate the ongoing trends of process variables associated with particular alarms after those alarms become active may lead to incorrect assumptions about the state of a process control system and/or a root cause, an incorrect understanding of the behavior of process variables leading up to the triggering of corresponding alarms may also lead to improper root cause determinations and/or an ineffective response by operators.

Accordingly, the examples described herein involve a trend line graphic (herein referred to as a sparkline) that may be used to visually display the behavior of a process variable, both leading up to the triggering of an alarm (i.e., becoming active) as well as the behavior of the process variable subsequent to when the alarm is triggered. The displayed sparklines may have a fixed height and width and may not include labels or scales but present the changing relationship of a process variable to a corresponding alarm limit during a most recent period of time. The sparklines enable operators to quickly scan an alarm presentation display rather than having to read relevant information to understand the behavior and/or state of process variables relative to corresponding alarm limits. Additionally, the sparklines enable operators to determine whether the evolving state of a process variable associated with active alarms corresponds to an acceptable condition associated with normal behavior or is an unusual deviation from expected behavior that may require special attention. Furthermore, because the ongoing behavior of a process variable is displayed, operators can also recognize when their actions are working to correct potential problems or when they may need to take further and/or different action(s).

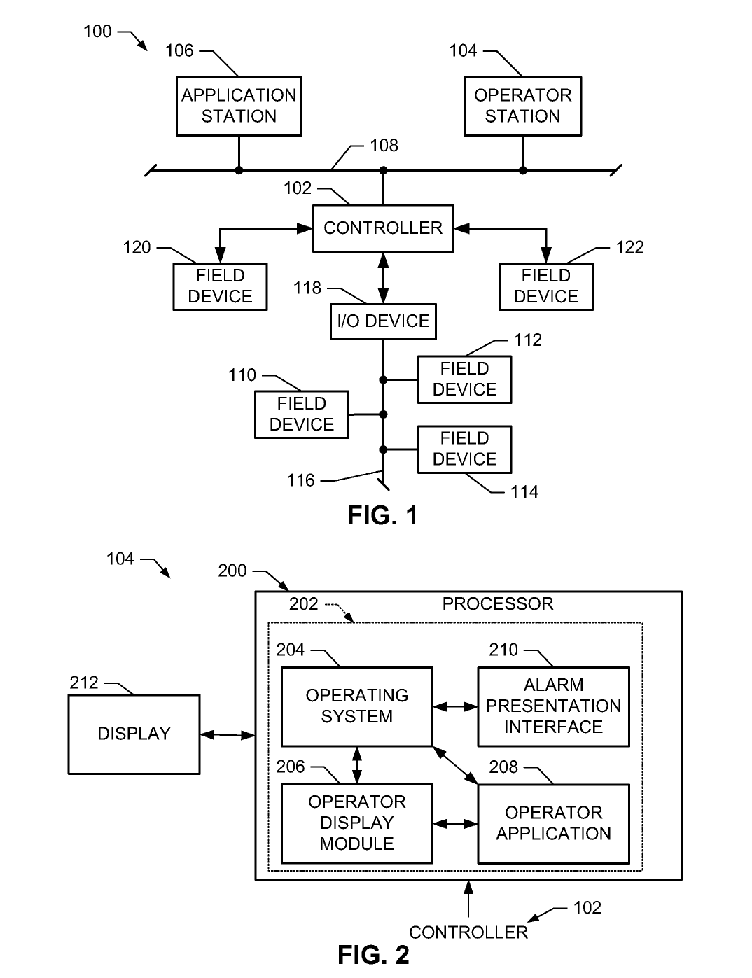

FIG. 1 is a schematic illustration of an example process control system 100. The example process control system 100 of FIG. 1 includes one or more process controllers (one of which is designated at reference numeral 102), one or more operator stations (one of which is designated at reference numeral 104), and one or more workstations (one of which is designated at reference numeral 106). The example process controller 102, the example operator station 104 and the example workstation 106 are communicatively coupled via a bus and/or local area network (LAN) 108, which is commonly referred to as an application control network (ACN).

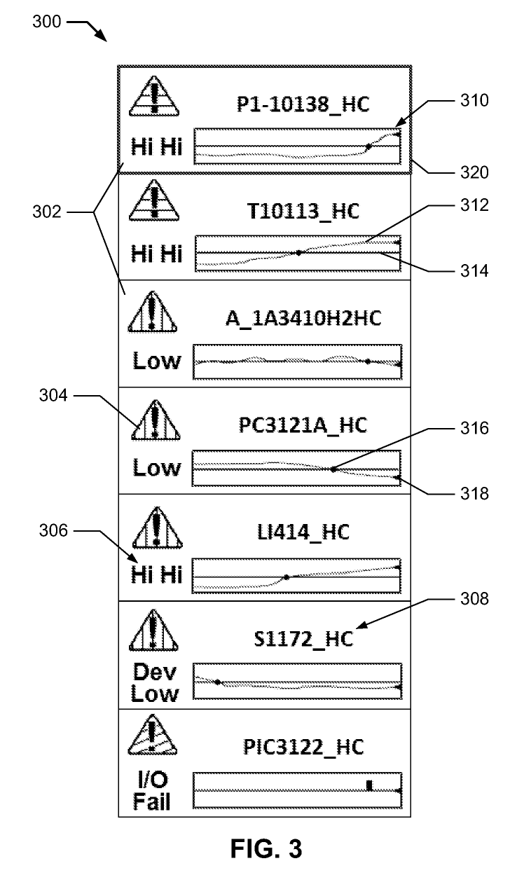

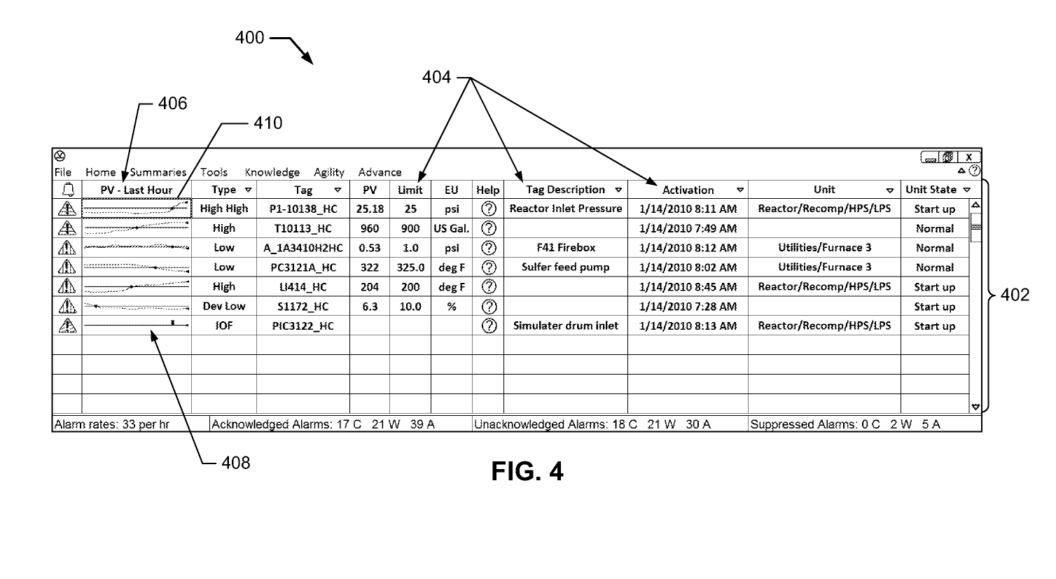

The example operator station 104 of FIG. 1 allows an operator to review and/or operate one or more operator display screens and/or applications that enable the operator to view process control system variables, view process control system states, view process control system conditions, view process control system alarms, and/or change process control system settings (e.g., set points, operating states, clear alarms, silence alarms, etc.). An example manner of implementing the example operator station 104 of FIG. 1 is described below in connection with FIG. 2. Example operator display applications that may be used to implement the example operator station 104 are described below in connection with FIGS. 3 and 4.

The example operator station 104 includes and/or implements an alarm presentation interface (e.g., the example alarm presentation interfaces of FIGS. 3 and 4) to display a sparkline associated with each active alarm to enable process control system operators to visually perceive the behavior of a process variable associated with each of the active alarms during a period of time leading up to the alarm becoming active and after the alarm is active up to the current state of the process variable. In some examples, the sparkline associated with each active alarm may be displayed within a column of a conventional alarm list (e.g., the example alarm presentation interface of FIG. 4) alongside additional information related to each alarm. In other examples, the sparkline associated with each active alarm may be displayed as an independent interface or as a sidebar banner in conjunction with other elements of an alarm presentation interface (e.g., the example alarm presentation interface of FIG. 4).

The example workstation 106 of FIG. 1 may be configured as an application station to perform one or more information technology applications, user-interactive applications and/or communication applications. For example, the application station 106 may be configured to perform primarily process control-related applications, while another application station (not shown) may be configured to perform primarily communication applications that enable the process control system 100 to communicate with other devices or systems using any desired communication media (e.g., wireless, hardwired, etc.) and protocols (e.g., HTTP, SOAP, etc.). The example operator station 104 and the example workstation 106 of FIG. 1 may be implemented using one or more workstations and/or any other suitable computer systems and/or processing systems. For example, the operator station 104 and/or workstation 106 could be implemented using single processor personal computers, single or multi-processor workstations, etc.

The example LAN 108 of FIG. 1 may be implemented using any desired communication medium and protocol. For example, the example LAN 108 may be based on a hardwired and/or wireless Ethernet communication scheme. However, as will be readily appreciated by those having ordinary skill in the art, any other suitable communication medium(s) and/or protocol(s) could be used. Further, although a single LAN 108 is illustrated in FIG. 1, more than one LAN and/or other alternative pieces of communication hardware may be used to provide redundant communication paths between the example systems of FIG. 1.

The example controller 102 of FIG. 1 is coupled to a plurality of smart field devices 110, 112 and 114 via a digital data bus 116 and an input/output (I/O) gateway 118. The smart field devices 110, 112, and 114 may be Fieldbus compliant valves, actuators, sensors, etc., in which case the smart field devices 110, 112, and 114 communicate via the digital data bus 116 using the well-known Foundation Fieldbus protocol. Of course, other types of smart field devices and communication protocols could be used instead. For example, the smart field devices 110, 112, and 114 could instead be Profibus and/or HART compliant devices that communicate via the data bus 116 using the well-known Profibus and HART communication protocols. Additional I/O devices (similar and/or identical to the I/O gateway 118 may be coupled to the controller 102 to enable additional groups of smart field devices, which may be Foundation Fieldbus devices, HART devices, etc., to communicate with the controller 102.

In addition to the example smart field devices 110, 112, and 114, one or more non-smart field devices 120 and 122 may be communicatively coupled to the example controller 102. The example non-smart field devices 120 and 122 of FIG. 1 may be, for example, conventional 4-20 milliamp (mA) or 0-10 volts direct current (VDC) devices that communicate with the controller 102 via respective hardwired links.

The example controller 102 of FIG. 1 may be, for example, a DeltaV™ controller sold by Fisher-Rosemount Systems, Inc., an Emerson Process Management company. However, any other controller could be used instead. Further, while only one controller 102 is shown in FIG. 1, additional controllers and/or process control platforms of any desired type and/or combination of types could be coupled to the LAN 108. In any case, the example controller 102 performs one or more process control routines associated with the process control system 100 that have been generated by a system engineer and/or other system operator using the operator station 104 and which have been downloaded to and/or instantiated in the controller 102.

While FIG. 1 illustrates an example process control system 100 within which the methods and apparatus to control information presented to process control system operators described in greater detail below may be advantageously employed, the methods and apparatus to control information presented to operators described herein may, if desired, be advantageously employed in other process plants and/or process control systems of greater or less complexity (e.g., having more than one controller, across more than one geographic location, etc.) than the illustrated example of FIG. 1.

FIG. 2 illustrates an example manner of implementing the example operator station 104 of FIG. 1. The example operator station 104 of FIG. 2 includes at least one programmable processor 200. The example processor 200 of FIG. 2 executes coded instructions present in a main memory 202 of the processor 200 (e.g., within a random-access memory (RAM) and/or a read-only memory (ROM)). The processor 200 may be any type of processing unit, such as a processor core, a processor and/or a microcontroller. The processor 200 may execute, among other things, an operating system 204, an operator display module 206, an operator application 208, and an alarm presentation interface 210. An example operating system 204 is an operating system from Microsoft®. The example main memory 202 of FIG. 2 may be implemented by and/or within the processor 200 and/or may be one or more memories and/or memory devices operatively coupled to the processor 200.

To allow an operator to interact with the example processor 200, the example operator station 104 of FIG. 2 includes any type of display 212. Example displays 212 include, but are not limited to, a computer monitor, a computer screen, a television, a mobile device (e.g., a smart phone, a Blackberry™ and/or an iPhone™), etc. capable of displaying user interfaces and/or applications implemented by the processor 200 and/or, more generally, the example operator station 104.

The example operating system 204 of FIG. 2 displays and/or facilitates the display of the alarm presentation interface 210 by and/or at the example display 212. To facilitate operator interactions with applications implemented by the example operator station 104, the example operating system 204 implements an application programming interface (API) by which the example operator display module 206 can define and/or select the alarm presentation interface 210 via the operator application 208, and cause and/or instruct the operating system 204 to display the defined and/or selected alarm presentation interface 210. An example alarm presentation interface 210 is described below in connection with FIGS. 3 and 4.

To present process control system operator displays and/or applications, the example operator station 104 of FIG. 2 includes the example operator display module 206. The example operator display module 206 of FIG. 2 collects alarm data and/or information from one or more process controllers (e.g., the example controller 102 of FIG. 1) and/or other elements of a process control system, and uses the collected alarm data and/or information to create and/or define a particular alarm presentation interface 210 (e.g., the example alarm presentation interface 300 of FIG. 3) via the operator application 208. While doing so, the example operator display module 206 also temporarily stores or buffers process variable data corresponding to all enabled and unsuppressed alarms or any predefined subset of the alarms of certain types (e.g., module and safety instrumented system (SIS) alarms) for a most recent period of time. The buffered process variable data may then be accessed to create and/or define a sparkline to be included in the alarm presentation interface 210 that graphically displays the historical behavior of the process variable relative to a corresponding alarm limit over the time period the data is buffered in the event that a corresponding alarm is subsequently triggered. The buffering of all the process variables may be accomplished without any user setup and may be done independent of any long term historization features in the process control system. The created and/or defined alarm presentation interface 210 is displayed at the example display 212 by and/or via the example operating system 204.

While an example manner of implementing the example operator station 104 of FIG. 1 has been illustrated in FIG. 2, the data structures, elements, processes and devices illustrated in FIG. 2 may be combined, divided, re-arranged, omitted, eliminated and/or implemented in any other way. Further, the example operating system 204, the example operator display module 206, the example alarm presentation interface 210, and/or, more generally, the example operator station 104 of FIG. 2 may be implemented by hardware, software, firmware and/or any combination of hardware, software and/or firmware. Further still, the example operator station 104 may include additional elements, processes and/or devices instead of, or in addition to, those illustrated in FIG. 2, and/or may include more than one of any or all of the illustrated data structures, elements, processes and devices.

FIG. 3 illustrates an example alarm presentation interface 300 that may be used to implement an operator display and/or application and/or, more generally, the example operator station 104 of FIG. 1. The example alarm presentation interface 300 may be displayed as an independent interface or as a sidebar alarm banner in conjunction with other elements (not shown) of an alarm presentation interface. The alarm presentation interface 300 includes alarm boxes 302 that contain basic information concerning each active alarm of a process control system including an alarm priority (indicated by the shape and/or color of an icon 304), an alarm type (indicated by a label 306), and an alarm tag 308 to identify the alarm corresponding to the alarm box 302. The alarm boxes 302 also include sparklines 310 corresponding to each active alarm. Each sparkline 310 includes a trend line 312 representing the behavior of a process variable in relation to an alarm limit represented by an alarm limit line 314 over a most recent period of time (e.g., the past hour).

The current state of the process variable corresponding to the sparkline 310 may be represented graphically by, for example, an icon such as a tick mark 318, located at the rightmost end of the trend line 312. The horizontal scale corresponds to the most recent period of time, for which the process variable data is buffered. The time of activation of the alarm is represented graphically on the sparkline 310, for example, by another icon such as a dot 316. As time passes between when the alarm was first activated (i.e., when the process variable crossed the alarm limit) and the current time, the dot 316 moves left along the alarm limit line 314 until more time elapses than corresponds to the width of the sparkline 310, at which point the dot 316 is no longer displayed. Furthermore, every sparkline 310 in the alarm presentation interface 300 may be fixed to a common width and a common timescale and vertically aligned (e.g., by placing the alarm boxes 302 in a vertical column) to enable operators to make a quick visual comparison between multiple alarms and recognize potentially interacting process variables.

As shown in FIG. 3, each sparkline 310 does not contain labels or scales to quantify the magnitude of variation of the corresponding process variable. However, the vertical scale of each sparkline 310 is automatically adjusted to fit within a fixed height to enable an operator to quickly recognize the volatility of a process variable as well as the current slope and direction of the process variable relative to a corresponding alarm limit. Furthermore, the example alarm presentation interface 300 may highlight (e.g., with a red border 320) or otherwise change the appearance of the alarm box 302 when the difference between a process variable and a corresponding alarm limit is increasing based on a most recent portion (e.g., last 30 seconds) of the time period displayed in the sparkline 310. Visually signaling when a process variable is diverging from a normal condition enables operators to quickly spot alarms that may need additional action to correct the direction of the process variable without risking confusion as to whether a process variable increasing or decreasing corresponds to an acceptable condition or a problematic condition.

FIG. 4 illustrates another example alarm presentation interface 400. The alarm presentation interface 400 includes an alarm list 402 that contains a list of active alarms in a process control system with columns 404 including relevant information corresponding to each alarm listed in the alarm list 402. The example alarm list 402 includes a sparkline column 406 that contains a sparkline 408 corresponding to each alarm included in the alarm list 402. The sparklines 408 are implemented in the same way as discussed above in connection with FIG. 3. However, because the sparklines 408 are not included within an alarm box 302, when a process variable is diverging from a corresponding alarm limit, the sparkline 408 is highlighted (e.g., with a red border 410) to graphically inform operators of the alarms corresponding to a process condition that may require action.

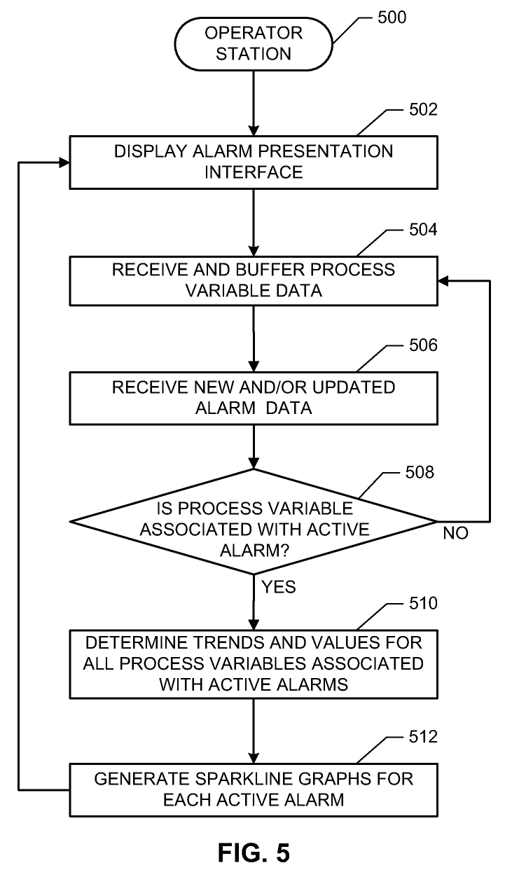

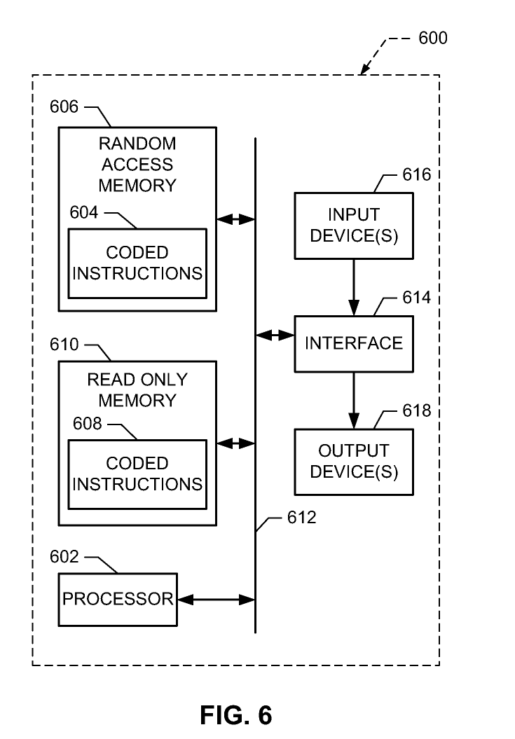

FIG. 5 is a flowchart representative of an example process for implementing the example operator station 104 of FIGS. 1 and/or 2. The example process of FIG. 5 may be carried out by a processor, a controller and/or any other suitable processing device. For example, the process of FIG. 5 may be embodied in coded instructions (e.g., computer readable instructions) stored on a tangible machine accessible or readable medium such as a flash memory, a ROM and/or random-access memory RAM associated with a processor (e.g., the example processor 602 discussed below in connection with FIG. 6). As used herein, the term tangible computer readable medium is expressly defined to include any type of non-transitory computer readable storage (and to exclude propagating signals), or any other storage media in which information is stored for any duration (e.g., for extended time periods, permanently, brief instances, for temporarily buffering, and/or for caching of the information).

Alternatively, some or all of the example operations of FIG. 5 may be implemented using any combination(s) of application specific integrated circuit(s) (ASIC(s)), programmable logic device(s) (PLD(s)), field programmable logic device(s) (FPLD(s)), discrete logic, hardware, firmware, etc. Also, one or more of the operations depicted in FIG. 5 may be implemented manually or as any combination of any of the foregoing techniques, for example, any combination of firmware, software, discrete logic and/or hardware. Further, although the example process of FIG. 5 is described with reference to the flowchart of FIG. 5, persons of ordinary skill in the art will readily appreciate that many other methods of implementing the example process of FIG. 5 may be employed. For example, the order of execution of the blocks may be changed, and/or some of the blocks described may be changed, eliminated, sub-divided, or combined. Additionally, any or all of the example operations of FIG. 5 may be carried out sequentially and/or carried out in parallel by, for example, separate processing threads, processors, devices, discrete logic, circuits, etc.

The process of FIG. 5 begins at block 500 with an operator station (e.g., the example operator station 104 of FIG. 2) running an operator display module (e.g., the example operator display module 206) to display an alarm presentation interface (e.g., the example alarm presentation interface 210) at block 502. At block 504, the operator station (e.g., the example operator station 104) receives process variable data for all enabled unsuppressed alarms or any predefined subset of the alarms of certain types (e.g., module and SIS alarms) and buffers the data over a most recent period of time. At block 506, the operator station (e.g., the example operator station 104) receives new and/or updated alarm data via process controllers (e.g., the example controller 102). At block 508, an operator application (e.g., the example operator application 208) determines whether the data for each buffered process variable corresponds to an active alarm. For each buffered process variable that does not correspond to an active alarm, the process returns to block 504 to continue buffering the process variable. For each process variable that does correspond to an active alarm, the process moves to block 510 where the operator application (e.g., the example operator application 208) determines the current trend for the process variables (i.e., whether the process variable is diverging or converging with the corresponding alarm limit) and the current state for the process variables. At block 512, the operator application (e.g., the example operator application 208) generates and/or updates a sparkline corresponding to each active alarm as well as determines other changes to be made to the alarm presentation interface (e.g., the example alarm presentation interface 210) and then notifies the operator display module (e.g., the example operator display module 206) of the changes. Control then returns to block 502 to display the updated alarm presentation interface (e.g., the example alarm presentation interface 210).

FIG. 6 is a schematic diagram of an example processor platform 600 that may be used and/or programmed to carry out the example process of FIG. 5 and/or, more generally, to implement the example operator station 104 of FIGS. 1 and/or 2. For example, the processor platform 600 can be implemented by one or more general purpose processors, processor cores, microcontrollers, etc.

The processor platform 600 of the example of FIG. 6 includes at least one general purpose programmable processor 602. The processor 602 executes coded instructions 604 and/or 608 present in main memory of the processor 602 (e.g., within a RAM 606 and/or a ROM 610). The processor 602 may be any type of processing unit, such as a processor core, a processor and/or a microcontroller. The processor 602 may execute, among other things, the example process of FIG. 5 to implement the example operator stations 104 described herein. The processor 602 is in communication with the main memory (including the ROM 610 and/or the RAM 606) via a bus 612. The RAM 606 may be implemented by DRAM, SDRAM, and/or any other type of RAM device, and the ROM 610 may be implemented by flash memory and/or any other desired type of memory device. Access to the memories 606 and 610 may be controlled by a memory controller (not shown).

The processor platform 600 also includes an interface circuit 614. The interface circuit 614 may be implemented by any type of interface standard, such as a USB interface, a Bluetooth interface, an external memory interface, serial port, general purpose input/output, etc. One or more input devices 616 and one or more output devices 618 are connected to the interface circuit 614. The input devices 616 and/or output devices 618 may be used to, for example, provide the alarm presentation interface 210 to the example display 212 of FIG. 2.

Although certain example methods, apparatus and articles of manufacture have been described herein, the scope of coverage of this patent is not limited thereto. Such examples are intended to be non-limiting illustrative examples. On the contrary, this patent covers all methods, apparatus and articles of manufacture fairly falling within the scope of the appended claims either literally or under the doctrine of equivalents.

What is claimed is:

1. An operator interface apparatus for a process control system comprising:
a display;
an operator display module to present an operator application on the display; and
an alarm presentation interface to be presented on the display via the operator application, wherein the alarm presentation interface includes a sparkline associated with an alarm to graphically indicate a trend of a process variable relative to an alarm limit associated with the alarm.

2. An operator interface apparatus as defined in claim 1, wherein a vertical scale of the sparkline is automatically adjusted to fit a fixed height of the sparkline.

3. An operator interface apparatus as defined in claim 1, wherein the sparkline associated with the alarm has a width and timescale equal to a second sparkline associated with a second alarm to enable the operator to visually compare the first and second sparklines.

4. An operator interface apparatus as defined in claim 1, wherein the sparkline includes the trend of the process variable during a period of time before the alarm is triggered.

5. An operator interface apparatus as defined in claim 1, wherein the sparkline includes the trend of the process variable during a period of time after the alarm is triggered.

6. An operator interface apparatus as defined in claim 1, wherein the sparkline includes the trend of the process variable during a most recent period of time.

7. An operator interface apparatus as defined in claim 6, further comprising a memory to buffer data associated with the trend of the process variable for the most recent period of time independent of a long-term historization of trend data of the process variable.

8. An operator interface apparatus as defined in claim 6, wherein the sparkline includes a graphic indication of when the alarm was triggered relative to the most recent period of time.

9. An operator interface apparatus as defined in claim 1, wherein the sparkline includes a graphic indication of a current state of the process variable relative to the alarm limit.

10. An operator interface apparatus as defined in claim 1, wherein the sparkline is incorporated into an alarm list of the alarm presentation interface.

11. An operator interface apparatus as defined in claim 1, wherein the sparkline is incorporated into a side-bar banner display of the alarm presentation interface.

12. An operator interface apparatus as defined in claim 1, wherein the sparkline is highlighted when the difference between the process variable and the alarm limit is increasing to graphically indicate to the operator when further action may be needed to correct the process variable.

13. A method comprising:
receiving process variable data from a process controller associated with a process variable;
receiving alarm data of an alarm associated with the process variable;
generating a sparkline based on the process variable data and the alarm data to graphically indicate a trend of the process variable relative to an alarm limit of the alarm; and
displaying the sparkline via an operator interface.

14. A method as defined in claim 13, further comprising automatically adjusting a vertical scale of the sparkline to fit a fixed height of the sparkline.

15. A method as defined in claim 13, wherein the sparkline associated with the alarm has a width and a timescale equal to a second sparkline associated with a second alarm to enable an operator to visually compare the first and second sparklines.

16. A method as defined in claim 13, wherein the sparkline includes the trend of the process variable during a period of time before the alarm is triggered.

17. A method as defined in claim 13, wherein the sparkline includes the trend of the process variable during a period of time after the alarm is triggered.

18. A method as defined in claim 13, wherein the trend of the process variable includes a most recent period of time.

19. A method as defined in claim 18, further comprising buffering the process variable data for an amount of time equal to the most recent period of time independent of a long-term historization of the process variable data.

20. A method as defined in claim 13, further comprising highlighting the sparkline when the difference between the process variable and the alarm limit is increasing to graphically indicate to an operator when further action may be needed to correct the process variable.

21. A tangible article of manufacture storing machine readable instructions which,
when executed, cause a machine to:
receive process variable data associated with a process variable;
receive alarm data associated with the process variable;
generate a sparkline based on the process variable data and the alarm data to graphically indicate a trend of the process variable relative to an alarm limit; and
display the sparkline via an operator interface.

22. A tangible article of manufacture as defined in claim 21, wherein the sparkline includes a graphic indication of when the alarm was triggered relative to a most recent period of time.

23. A tangible article of manufacture as defined in claim 21, wherein the instructions, when executed, further cause the machine to buffer the process variable data for an amount of time equal to a most recent period of time independent of a long-term historization of the process variable data.

24. A tangible article of manufacture as defined in claim 21, wherein the instructions, when executed, cause the machine to highlight the sparkline when the difference between the process variable and the alarm limit is increasing to graphically indicate to an operator when further action may be needed to correct the process variable.
